(19) United States
(12) Patent Application Publication
(10) Pub. No.: US 2014/0209164 A1
(43) Pub. Date: Jul. 31, 2014

(54) SOLAR CELL MODULE

(71) Applicant: Panasonic Corporation, Osaka (JP)

(72) Inventors: YOSHIYUKI KUDOH, Shiga (JP); KAZUMICHI SHIMIZU, Osaka (JP)

(73) Assignee: Panasonic Corporation, Osaka (JP)

(21) Appl. No.: 14/162,736

(22) Filed: Jan. 24, 2014

(30) Foreign Application Priority Data
Jan. 29, 2013 (JP) 2013-014432

(51) Int. Cl. H01L 31/05

(52) U.S. Cl. CPC H01L 31/05
USPC 136/256

(57) ABSTRACT

A solar cell module that has enhanced output characteristics is provided. The solar cell module contains a solar cell, a wiring material and a resin adhesive layer. The solar cell has first and second electrodes on one of its principal surfaces. The wiring material is electrically connected to the solar cell. The resin adhesive layer adheres the solar cell to the wiring material. The wiring material has an insulating substrate and a wiring on the insulating substrate. The wiring is electrically connected to the first or second electrode. The wiring has a transversal cross section having an edge length on a side opposite to the insulating substrate that is smaller than an edge length on a side of the insulating substrate.

### CROSS REFERENCE TO RELATED APPLICATIONS

The present application claims the benefit of foreign priority to Japanese Patent Application No. 2013-014432, filed on Jan. 29, 2013, the contents of which are incorporated herein by reference.

### BACKGROUND

1. Technical Field

The technical field relates to a solar cell module.

2. Background Art

Known examples of a solar cell module capable of achieving high output characteristics include a solar cell module having a back junction solar cell in which first and second electrodes are provided on the back surface thereof (see, for example, JP-A-2012-142456).

In the solar cell module described in JP-A-2012-I42456, plural solar cells are electrically connected with a printed circuit board. The wiring of the printed circuit board is electrically connected to a finger part of the first or second electrode of the solar cell JPA-2012-142456 describes that the printed circuit board and the solar cells may be adhered to each other with a resin adhesive having anisotropic conductivity.

### SUMMARY

However, there is a demand for further enhancing the output characteristics of a solar cell module.

An object of this disclosure is to provide a solar cell module that has enhanced output characteristics.

According to one embodiment, a solar cell module is provided that contains a solar cell, a wiring material and a resin adhesive layer. The solar cell has first and second electrodes on one of principal surfaces thereof. The wiring material is electrically connected to the solar cell. The resin adhesive layer adheres the solar cell to the wiring material The wiring material has an insulating substrate and a wiring. The wiring is on the insulating substrate The wiring is electrically connected to the first or second electrode. The wiring has a transversal cross section having an edge length on a side opposite to the insulating substrate that is smaller than an edge length on a side of the insulating substrate.

According to the embodiment, a solar cell module that has enhanced output characteristics is provided.

### BRIEF DESCRIPTION OF THE DRAWINGS

FIG. 1 is a schematic plan view of a solar cell module according to one embodiment.

FIG. 2 is a schematic cross sectional view of a solar cell module according to one embodiment.

FIG. 3 is a schematic back surface view of a solar cell according to one embodiment.

FIG. 4 is a schematic back surface view of a part of a solar cell module according to one embodiment, in which first and second protective members and a filler layer are not shown.

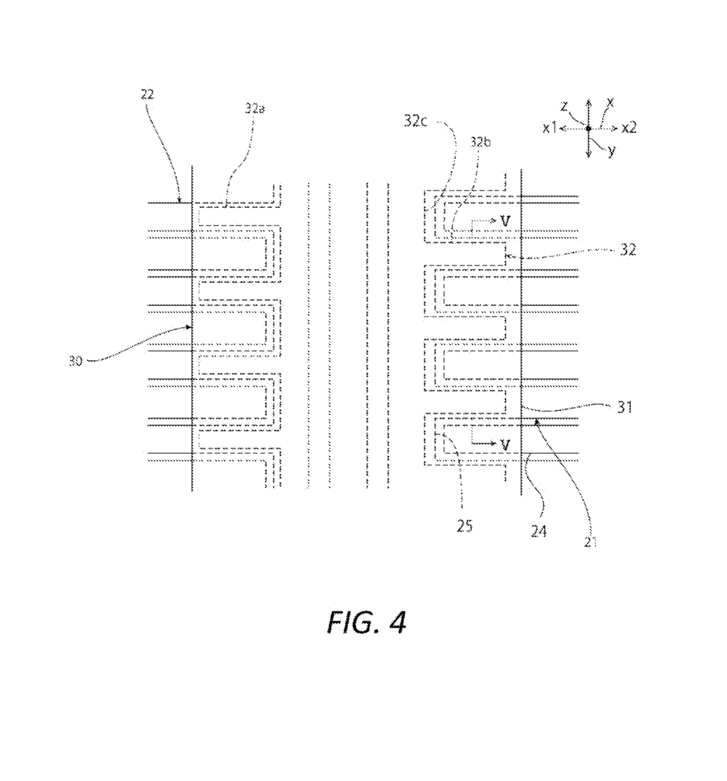

FIG. 5 is a schematic cross sectional view of the portion shown by V-V in FIG. 4.

FIG. 6 is a schematic cross sectional view of a solar cell and a wiring material according to a modified embodiment.

FIG. 7 is a schematic cross sectional view of a solar cell and a wiring material according to another modified embodiment.

### DETAILED DESCRIPTION

Examples of preferred embodiments will be described below The embodiments shown below are only examples.

In the drawings referred in the embodiments or the like, members having substantially the same function are shown by the same symbol. The drawings referred to in the embodiments or the like are schematic illustrations, in which the dimensional ratios of the articles and the like shown in the drawings may be different from the dimensional ratios of the actual articles in some cases. The dimensional ratios of the articles and the like may be different among the drawings in some cases. The dimensional ratios of the actual articles and the like may be determined in consideration of the following descriptions.

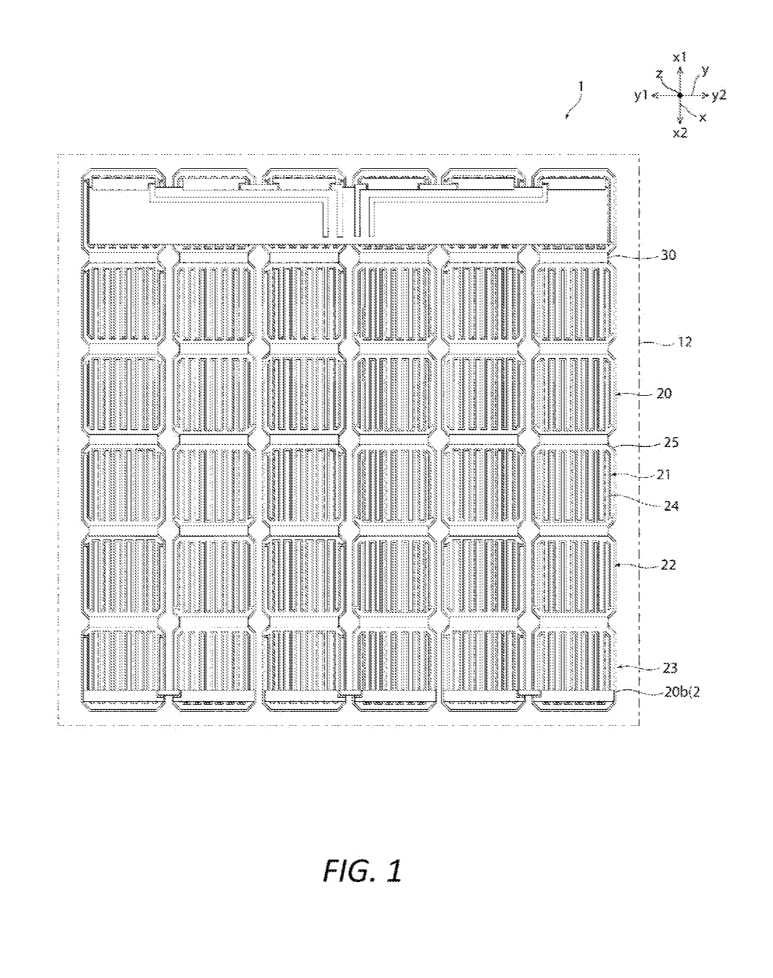

As shown in FIG. 1, a solar cell module 1 has plural solar cells 20. The plural solar cells 20 are electrically connected with a wiring material 30.

The plural solar cells 20 are disposed in a filler layer 13, which is filled between a first protective member 11 and a second protective member 12. The first protective member 11 may be constituted for example, by a glass plate, a resin plate or a ceramic plate. The second protective member 12 may be constituted, for example, by a resin sheet, a resin sheet having a barrier layer, such as a metal layer or an inorganic oxide layer, a glass plate, a resin plate or a ceramic plate. The filler layer 13 may be constituted, for example, by a crosslinked resin, such as an ethylene-vinyl acetate copolymer (EVA), or a non-crosslinked resin, such as a polyolefin.

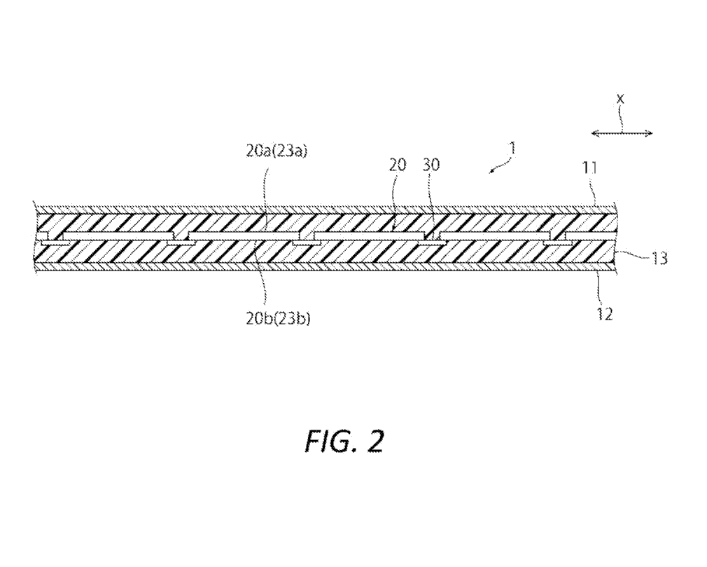

As shown in FIG. 2, the solar cell 20 has a light receiving surface 20a and a back surface 20b. In the solar cell 20, the light receiving surface 20a is disposed to be directed to the first protective member 1 and the back surface 20b is disposed to be directed to the second protective member 12. The light receiving surface referred to herein is one of the pair of principal surfaces of the solar cell that mainly receives light, and the other of the principal surfaces constitutes the back surface.

The solar cell 20 has a photoelectric conversion part 23 The photoelectric conversion part 23 generates carriers, such as electrons or holes, on receiving light. The photoelectric conversion part 23 may have, for example, a crystalline semiconductor plate. The photoelectric conversion part 23 has first and second principal surfaces 23a and 23b. The first principal surface 23a constitutes the light receiving surface 20a. The second principal surface 23b constitutes the back surface 20b.

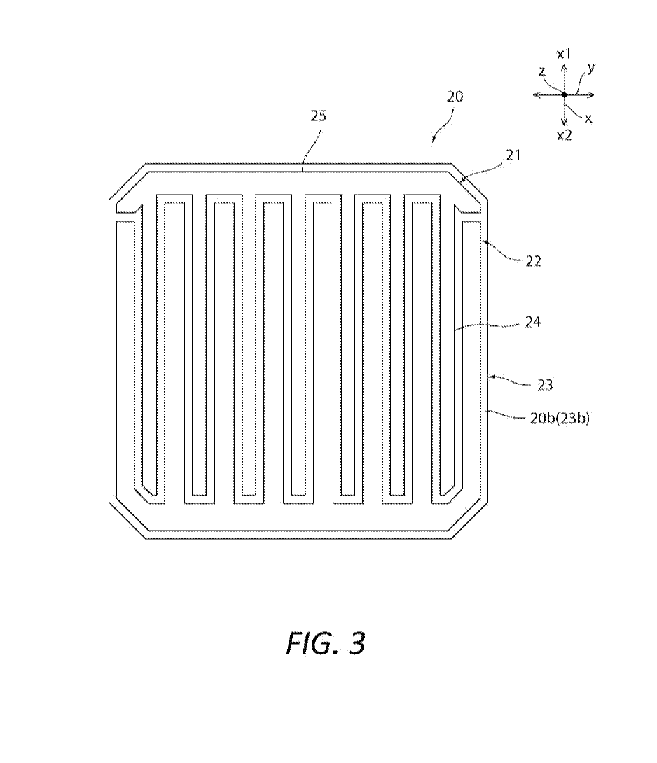

As shown in FIG. 3, a first electrode 21 and a second electrode 22 are provided on the second principal surface 23b. The first electrode 21 and the second electrode 22 each have plural finger parts 24 and a busbar part 25. In the embodiment, however, the first and second electrodes each may be constituted only by the plural finger parts without having the busbar part.

The plural finger parts 24 extend along the x axis direction. The plural finger parts 24 are disposed with distances therebetween in the y axis direction. The finger parts 24 of the first electrode 21 and the finger parts 24 of the second electrode 22 are disposed alternately in the y axis direction. In each of the first and second electrodes 21 and 22, the plural finger parts 24 are electrically connected to the busbar part 25.

The solar cells 20 that are adjacent to each other in the x axis direction are electrically connected to each other with the wiring material 30. Specifically, the first electrode 21 of one solar cell 20 of the solar cells 20 that are adjacent to each other in the x axis direction is electrically connected to the second electrode 22 of the other solar cell 20 with the wiring material 30.

The wiring material 30 has an insulating substrate 31 and a wiring 32. The insulating substrate 31 may be constituted, for example, by a resin sheet or a ceramic plate. The wiring 32 is provided on the insulating substrate 31. The wiring 32 is electrically connected to the finger parts 24. Specifically, the wiring 32 has plural first linear parts 32a, plural second linear parts 32b and a connecting part 32c. The connecting part 32c extends along the y axis direction.

The plural first linear parts 32a are electrically connected to the connecting part 32c. The plural first linear parts 32a each extend from the connecting part 32c in the x axis direction toward the side x1. The plural first linear parts 32a are disposed with distances therebetween in the y axis direction. At least a part of the plural first linear parts 32a is disposed on the finger parts 24 of the second electrode 22. The first linear part 32a is electrically connected to the finger parts 24 of the second electrode 22. Accordingly, the wiring 32 is electrically connected to the second electrode 22 at the finger parts 24.

The plural second linear parts 32b are electrically connected to the connecting part 32c. The plural second linear parts 32b each extend from the connecting part 32c in the x axis direction toward the side x2. The plural second linear parts 32b are disposed with distances therebetween in the y axis direction. At least a part of the plural second linear parts 32b is disposed on the finger parts 24 of the first electrode 21. The second linear part 32b is electrically connected to the finger parts 24 of the first electrode 21. Accordingly, the wiring 32 is electrically connected to the first electrode 21 at the finger parts 24. The first and second linear parts 32a and 32b each may be electrically connected to the first or second electrode 21 or 22 at the busbar part 25.

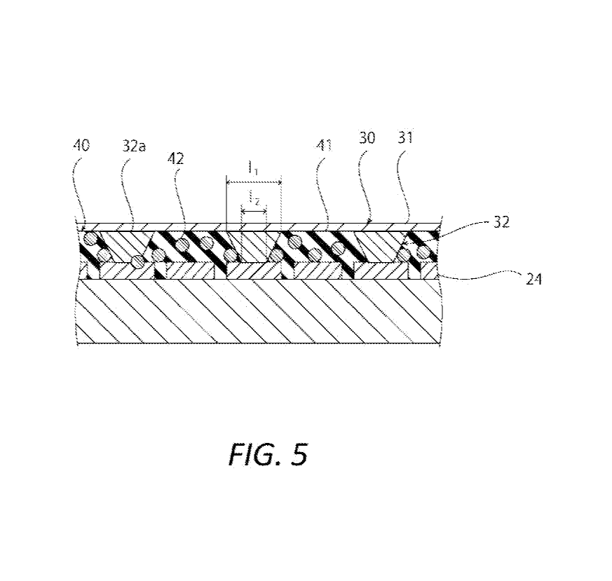

The solar cell 20 and the wiring material 30 are adhered to each other by a resin adhesive layer 40 shown in FIG. 5 The resin adhesive layer 40 contains an adhesive matrix 41 and electroconductive members 42. The adhesive matrix 41 is formed of a resin. Specifically, the adhesive matrix 41 contains a cured product of a resin adhesive The electroconductive members 42 are disposed in the adhesive matrix 41. The electroconductive members 42 are constituted by an electroconductive material at least in the surface layers thereof. Specifically, in the embodiment, the electroconductive members may have electroconductivity at least on the surface layers thereof, but the whole body thereof may not necessarily have electroconductivity. The electroconductive members 42 may be constituted, for example, by metal particles or by inorganic oxide particles having a metal layer coated thereon. The electroconductive members 42 preferably have a spherical shape. The resin adhesive layer 40 may not contain the electroconductive members 42.

As shown in FIG. 5, in the embodiment, the linear parts 32a and 32b of the wiring 32 each have a transversal cross section having an edge length l₂ on the side opposite to the insulating substrate 31 that is smaller than an edge length l₁ on the side of the insulating substrate 31. Thus, the area of the top surface of the linear parts 32a and 32b of the wiring 32 is smaller than the area of the bottom surface thereof. Therefore, the pressure applied to the top surface of the linear parts 32a and 32b on adhering the wiring material 30 and the solar cell 20 under pressure is larger than that in the ordinary products. Accordingly, the structure facilitates the resin adhesive layer 40, which intervenes between the linear parts 32a and 32b and the electrodes 21 and 22, to flow among the linear parts 32a and among the linear parts 32b, and thereby the linear parts 32a and the electrode 22, and the linear parts 32b and the electrode 21 each are in direct contact with each other. Thus, the electric resistances between the linear parts 32a and 32b and the electrodes 21 and 22 can be reduced. Furthermore, a larger pressure may be applied when the linear parts 32a and 32b are in direct contact with the electrode 21 and 22, and thereby the contact area at the interface between the linear parts 32a and 32b and the electrodes 21 and 22 can be increased to reduce the electric resistances between the linear parts 32a and 32b and the electrodes 21 and 22. Consequently, the solar cell module 1 achieves enhanced output characteristics and reliability, in the case where the electroconductive member 42 intervenes between the linear parts 32a and 32b and the electrodes 21 and 22, the linear parts 32a and 32b, the electroconductive member 42 and the electrodes 21 and 22 are deformed by a large pressure applied with the electroconductive member 42, and thereby the contact areas between the linear parts 32a and 32b and the electroconductive member 42 and between the electrodes 21 and 22 and the electroconductive ember 42 are increased. Accordingly, the electric resistances between the linear parts 32a and 32b and the electrodes 21 and 22 can be reduced. Consequently, the solar cell module 1 achieves enhanced output characteristics and reliability.

For providing the output characteristics and the reliability that are further enhanced, the area S₂ of the top surface of the linear parts 32a and 32b of the wiring 32 on the side opposite to the insulating substrate 31 and the area S₁ of the bottom surface thereof on the side of the insulating substrate 31 preferably satisfy the relationship, S₂≦0.9×S₁. This is because when the S₂ is larger than 0.9 time the area S₁, the pressure from the linear parts 32a and 32b may substantially not be increased. The areas S₁ and S₂ more preferably satisfy the relationship, S₂≧(1/3)S₁. This is because when the area S₂ is smaller than 1/3 of the area S₁, the electric resistance of the wiring 32 itself may be increased to deteriorate the output characteristics in some cases.

For providing the output characteristics and the reliability that are further enhanced, it is preferred that the tip ends of the linear parts 32a and 32b are in direct contact with the electrodes 21 and 22. Furthermore, it is preferred that the wiring 32 is electrically connected with the electrodes 21 and 22 through direct contact of the tip ends of the linear parts 32a and 32b with the electrodes 21 and 22, and simultaneously the wiring 32 is electrically connected with the electrodes 21 and 22 also with the electroconductive members 42.

The transversal cross sectional shape of the linear parts 32a and 32b is not limited to the tapered shape shown in FIG. 5. The transversal cross sectional shape of the linear parts 32a and 32b may be, for example, a trapezoidal shape, a domed shape or the like. The transversal cross sectional shape of the linear parts 32a and 32b may be, for example, such a shape that is once narrowed toward the side opposite to the insulating substrate 31 and then again expanded. This is because when the bottom edge length l₁ and the top edge length l₂ satisfy the relationship, l₂<l₁, the pressure applied to the top surface of the linear parts 32a and 32b on adhering the wiring material 30 and the solar cell 20 under pressure is increased. Furthermore, when the wiring 32 has a portion that is once narrowed, the deformation of the wiring 32 is facilitated during adhering under pressure. Thus, the wiring 32 is deformed following the relief structure on the electrodes 21 and 22, and thereby the electric resistances between the linear parts 32a and 32b and the electrodes 21 and 22 can be reduced. Consequently, the output characteristics and the reliability are enhanced.

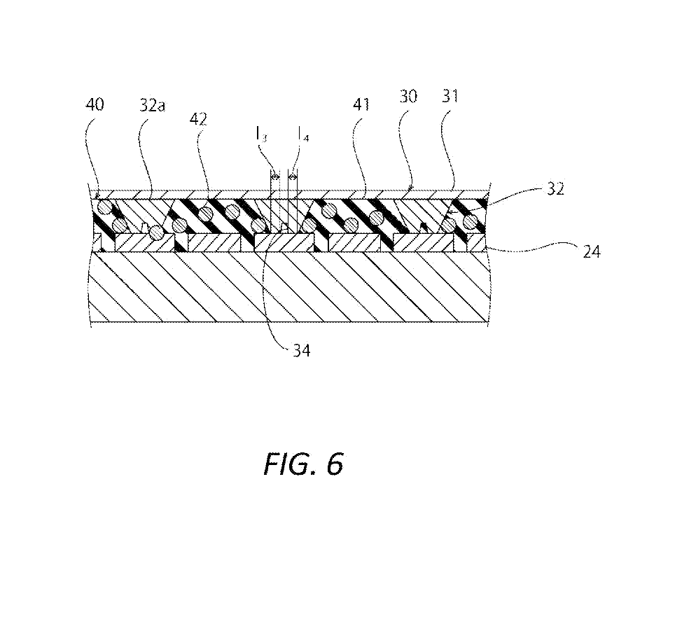

As shown in FIG. 6, a dent portion 34 may be provided on the top surface of the linear parts 32a and 32b, in this case, the top edge length l₂ is the length except for the part where the dent portion 34 is provided. In the case shown in FIG. 6, accordingly, the length l₂ is the sum of the length l₃ and the length l₄. The dent portion 34 provided may achieve such an effect that the pressure applied to the top surface of the linear parts 32a and 32b on adhering the wiring material 30 and the solar cell 20 under pressure is increased. Furthermore, a part of the resin adhesive layer 40 flows into the dent portion 34, and thereby the flow length thereof is shortened to increase the area where the linear parts 32a and the electrode 22, and the linear parts 32b and the electrode 21 each are in direct contact with each other. Thus, the electric resistances between the linear parts 32a and 32b and the electrodes 21 and 22 can be reduced. The number of the dent portion 34 provided is not limited to one, and plural dent portions may be provided. In this case, the top edge length l₂ is the sum of the lengths except for the parts where the dent portions 34 are provided. The dent portion 34 may reach, for example, the insulating substrate 31.

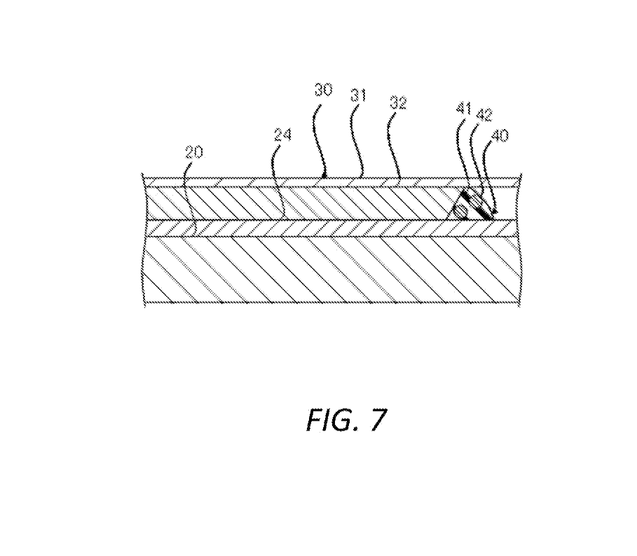

As shown in FIG. 7, furthermore, the linear parts 32 (32a and 32b) of the wiring 32 each may have a longitudinal cross section having an edge length of the linear parts 32a and 32b on the side opposite to the insulating substrate 31 that is smaller than the edge length on the side of the insulating substrate 31. In this case, the pressure applied to the top surface of linear parts 32a and 32b is increased, and thereby the contact area at the interface between the linear parts 32a and 32b and the electrodes 21 and 22 is increased to reduce the electric resistances between the linear parts 32a and 32b and the electrodes 21 and 22. Consequently, the output characteristics and the reliability are enhanced. In the case where the electroconductive member 42 intervenes between the linear parts 32a and 32b and the electrodes 21 and 22, the linear parts 32a and 32b, the electroconductive member 42 and the electrodes 21 and 22 are deformed by a large pressure applied with the electroconductive member 42, and thereby the contact areas between the linear parts 32a and 32b and the electroconductive member 42 and between the electrodes 21 and 22 and the electroconductive member 42 are increased. Accordingly, the electric resistances between the linear parts 32a and 32b and the electrodes 21 and 22 can be reduced. Consequently, the solar cell module 1 achieves enhanced output characteristics and reliability.

Among the above-mentioned various embodiments and modified examples, arbitrary embodiments or modified examples can be appropriately selected and combined to achieve their respective effects.

What is claimed is:

1. A solar cell module comprising:
a solar cell including first and second electrodes on one of principal surfaces thereof,
a wiring material that is electrically connected to the solar cell, and
a resin adhesive layer that adheres the solar cell to the wiring material,
wherein the wiring material includes:
an insulating substrate; and
a wiring that is on the insulating substrate and is electrically connected to the first or second electrode,
the wiring having a transversal cross section having an edge length on a side opposite to the insulating substrate that is smaller than an edge length on a side of the insulating substrate.

2. The solar cell module according to claim 1 herein the resin adhesive layer includes:
an adhesive matrix containing a resin; and
electroconductive members disposed in the adhesive matrix.

3. The solar cell module according to claim 2, wherein a tip end of the wiring is in direct contact with the first or second electrode.

4. The solar cell module according to claim 1, wherein
the first and second electrodes each have plural finger parts that extend in one direction, and
the wiring is electrically connected to the first or second electrode at the finger parts.

5. The solar cell module according, to claim 1, wherein an area S₁ of a bottom surface of the wiring on the side of the insulating substrate and an area S₂ of a top surface thereof on the side opposite to the insulating substrate satisfy the relationship, S₂≦0.9×S₁.
